(19) United States
(12) Patent Application Publication
(10) Pub. No.: US 2008/0272829 A1
(43) Pub. Date: Nov. 6, 2008

(54) SEMICONDUCTOR DEVICE INCLUDING MULTILAYER WIRING BOARD WITH POWER SUPPLY CIRCUIT

(75) Inventor: Takehiko Maeda, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 11/839,606

(22) Filed: Aug. 16, 2007

(30) Foreign Application Priority Data
Aug. 22, 2006 (JP) 2006-225889

(51) Int. Cl. G05F 1/00

(52) U.S. Cl. 327/518

(57) ABSTRACT

In one embodiment of the present invention, a semiconductor device includes a multilayer wiring board, a DC power supply circuit and a semiconductor integrated circuit chip. The multilayer wiring board has the semiconductor integrated circuit chip embedded therein. The DC power supply circuit is provided on the multilayer wiring board. The DC power supply circuit receives a power supply and converts a voltage of the power supply into a plurality of voltages having different levels from one another. The DC power supply circuit supplies a power supply voltage to the semiconductor integrated circuit chip.

### BACKGROUND OF THE INVENTION

1. Field of the Invention

The present invention relates to a semiconductor device.

2. Description of the Related Art

In recent years, in a most advanced semiconductor integrated circuit (semiconductor IC), there is a demand for a technique to achieve lower power consumption and miniaturization, in addition to higher performance and more sophisticated functions such as high-speed data processing for digital consumer equipment, mobile communication equipment, and the like. With the demand for higher performance and lower power consumption, reduction in voltage and increase in the number of power supplies of a core transistor have been advanced.

It should be noted that a related art relating to the present invention is disclosed in Japanese Laid-Open Patent Publication No. 2004-288793.

However, in the conventional semiconductor device including a semiconductor IC chip which uses a plurality of power supply voltages, it is necessary to provide a mounting board with a plurality of power supplies. That raises a problem in that a mounting area is increased.

### SUMMARY OF THE INVENTION

According to the present invention, there is provided a semiconductor device including: a multilayer wiring board having a semiconductor integrated circuit chip embedded therein; and a DC power supply circuit provided on said multilayer wiring board to receive a power supply. The DC power supply circuit supplies a power supply voltage to the semiconductor integrated circuit chip.

In the semiconductor device, the DC power supply circuit is provided on the multilayer wiring board having the semiconductor integrated circuit chip embedded therein. As a result, even in a case where the semiconductor integrated circuit chip uses a plurality of power supply voltages, there is no need to provide a mounting board with a plurality of power supplies, thereby making it possible to minimize a mounting area.

According to the present invention, a semiconductor device suitable for reducing the mounting area is realized.

### BRIEF DESCRIPTION OF THE DRAWINGS

In the accompanying drawings:

FIG. 1 is a cross-sectional diagram showing a semiconductor device according to a first embodiment of the present invention;

FIG. 2 is a block diagram for describing exchange of signals between a DC power supply circuit and a semiconductor IC chip;

FIG. 3 is a cross-sectional diagram showing a semiconductor device according to a second embodiment of the present invention;

FIG. 4 is a cross-sectional diagram showing a semiconductor device according to a third embodiment of the present invention;

FIG. 5 is a cross-sectional diagram showing a modified example of the semiconductor device shown in FIG. 4;

FIG. 6 is a cross-sectional diagram showing a modified example of the embodiments;

FIG. 7 is a cross-sectional diagram showing another modified example of the embodiments;

FIG. 8 is a cross-sectional diagram showing another modified example of the embodiments; and

FIG. 9 is a cross-sectional diagram showing another modified example of the embodiments.

### DETAILED DESCRIPTION OF THE PREFERRED EMBODIMENTS

Hereinafter, referring to the drawings, exemplary embodiments of a semiconductor device according to the present invention will be described. It should be noted that in the description of the drawings, the same components are denoted by the same reference symbols, and redundant descriptions thereof are omitted.

### First Embodiment

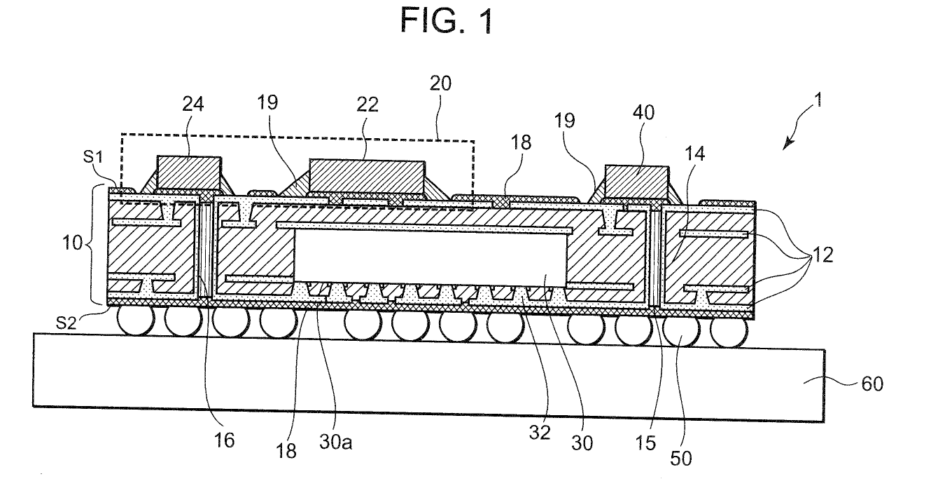

FIG. 1 is a cross-sectional diagram showing a semiconductor device according to a first embodiment of the present invention. A semiconductor device 1 includes a multilayer wiring board 10 and a DC power supply circuit 20. The multilayer wiring board 10 includes wirings 12, a resin layer 14, and penetrating through-holes 16. On side walls within the penetrating through-holes 16, the wirings 12 are formed. Each central portion within the penetrating through-holes 16 is buried with a resin layer 15. The wirings 12 provided within the penetrating through-holes 16 electrically connect an upper surface S1 to a lower surface S2 of the multilayer wiring board 10. In addition, a solder resist 18 is formed on both the surfaces S1 and S2 of the multilayer wiring board 10.

In the multilayer wiring board 10, a semiconductor IC chip 30 is embedded. The semiconductor IC chip 30 is included in the multilayer wiring board 10 with a circuit surface (i.e., surface on the wiring layer side) 30a facing the lower surface S2 side, and is connected to the wirings 12 through connection terminals 32 such as solder bumps. In this embodiment, the semiconductor IC chip 30 includes a plurality of functional blocks, and uses a plurality of voltages having different levels from one another. The functional blocks, for example, include a CPU, a memory, a phase locked loop (PLL), and an I/O portion.

The multilayer wiring board 10 is provided with the DC power supply circuit 20. In this embodiment, specifically, the DC power supply circuit 20 is provided on the upper surface S1 of the multilayer wiring board 10. The DC power supply circuit 20 is a circuit to supply a power supply voltage to the semiconductor IC chip 30. The DC power supply circuit 20 is composed of a plurality of electric components 22 and 24. The electric component 22 is a semiconductor component such as a DC-DC converter circuit, a regulator, or a switching element. The electric component 24 is a passive component such as a capacitor, an inductor, or a resistor. The electric components 22 and 24 are each electrically connected to the wirings 12 through a solder 19. The DC power supply circuit 20 is provided at a position where the DC power supply circuit 20 overlaps the semiconductor IC chip 30 in a plan view. Specifically, a part of the DC power supply circuit 20 (i.e., electric component 22) is provided at the position where the part of the DC power supply circuit 20 overlaps the semiconductor IC chip 30.

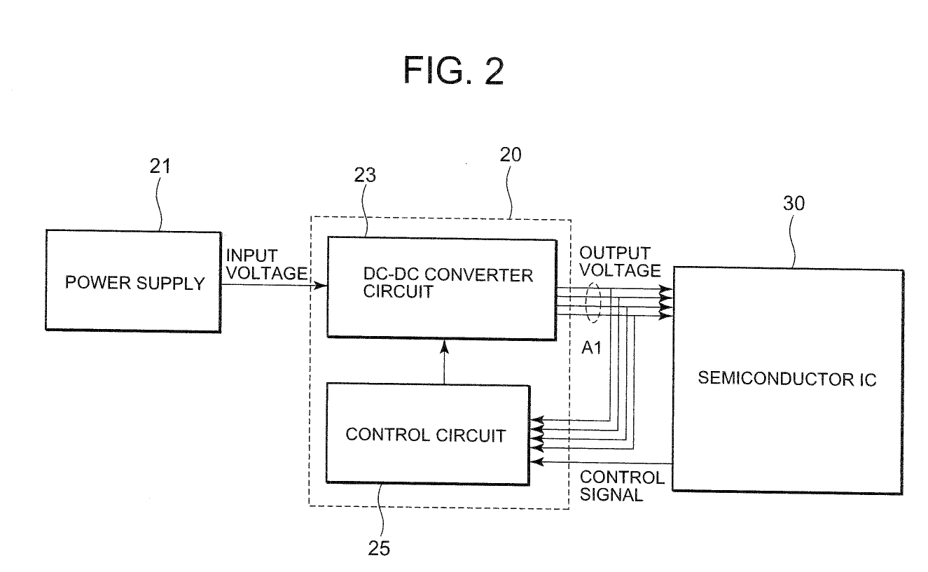

Referring to FIG. 2, exchange of signals between the DC power supply circuit 20 and the semiconductor IC chip 30 will be described. Here, a description is made of a case where the DC power supply circuit 20 includes a DC-DC converter circuit 23 and a control circuit 25, as an example. As shown in FIG. 2, the DC power supply circuit 20 receives a power supply 21, which supplies an input voltage to the DC power supply circuit 20. The DC-DC converter circuit 25 converts a voltage of the DC power supply circuit 20 into a plurality of voltages having different levels form one another. As indicated by the arrow A1 of FIG. 2, the DC power supply circuit 20 includes a plurality of (four in this example) output terminals. From those output terminals, voltages having different levels from one another are output. Those voltages are supplied to the semiconductor IC chip 30 as power supply voltages. For example, those voltages are supplied to each of the plurality of functional blocks in the semiconductor IC chip 30, as power supply voltages.

The output voltages of the DC power supply circuit 20 can be controlled by the semiconductor IC chip 30. Specifically, upon reception of a control signal from the semiconductor IC chip 30, the control circuit 25 controls voltages which are output from the DC-DC converter circuit 23 in response to the control signal. Through the control, for example, it is possible to change each level of the voltages output from the output terminals. It should be noted that it is not essential to supply all the plurality of output voltages from the DC power supply circuit 20 to the semiconductor IC chip 30. Only a part of the output voltages may be supplied thereto. In this case, it is also possible to determine which output voltage is to be supplied to the semiconductor IC chip 30, through the above-mentioned control.

Referring again to FIG. 1, a capacitor 40 is also provided on the upper surface S1 of the multilayer wiring board 10. The capacitor 40 functions as a decoupling capacitor. The capacitor 40 is electrically connected to the wirings 12 through the solder 19.

On the lower surface S2 of the multilayer wiring board 10, external connection terminals 50 are provided. The external connection terminals 50 are, for example, solder balls. The multilayer wiring board 10 is mounted on a mounting board 60 through the external connection terminals 50. The mounting board 60 is, for example, a printed circuit board.

Advantages of this embodiment will be described as follows. In the semiconductor device 1, the DC power supply circuit 20 is provided on the multilayer wiring board 10 having the semiconductor IC chip 30 embedded therein. As a result, even in a case where the semiconductor IC chip 30 uses a plurality of power supply voltages, there is no need to provide plurality of power supplies on the mounting board 60, thereby making it possible to minimize the mounting area.

On the other hand, when the DC power supply circuit is not provided on the multilayer wiring board, it is necessary to provide a plurality of power supply ICs on the mounting board, which results in increasing the mounting area. In this regard, according to this embodiment, it is sufficient to provide a single power supply IC (i.e., power supply for supplying an input voltage to DC power supply circuit 20) to the mounting board 60. In other words, even in a case where the semiconductor IC chip 30 uses a plurality of power supplies, it is sufficient to supply a single voltage from the mounting board 60. Accordingly, it is possible to reduce the area for the power supplies provided on the mounting board 60.

In recent years, with the achievement of lowering the power supply voltage, there is a strong demand for suppressing a voltage drop of the power supply due to wiring resistance the mounting board. Accordingly, in the conventional semiconductor device, it is necessary to dispose a plurality of power supply ICs in the vicinity of the semiconductor IC chip, which arises a problem in that a degree of freedom of layout for wirings and electric components on the mounting board is constrained. According to this embodiment, the DC power supply circuit 20 is provided on the multilayer wiring board 10, thereby preventing the problem from occurring.

Further, in the case where the be power supply circuit 20 is provided on the multilayer wiring board 10, it is possible to reduce a length of an electrical path between the DC power supply circuit 20 and the semiconductor IC chip 30, as compared with the case where the DC power supply circuit 20 is provided on the mounting board 60. As a result, the power supply voltage stabilizes, so the semiconductor device 1 can operate with stability also in a high-frequency band, that is, a GHz band or higher. Provision of the capacitor 40 contributes to further stabilization of the power supply voltage. Note that it is not essential to provide the capacitor 40.

In a case where the output voltage of the DC power supply circuit 20 is variable, it is possible to supply an optimum power supply voltage to the semiconductor IC chip 30 according to an operation mode for each functional block. For example, when a certain functional block is in a standby state, a power supply voltage supplied to the functional block is temporarily reduced, thereby making it possible to minimize the power consumption of the semiconductor device 1. At this time, the power supply voltage may be reduced to 0 V. On the contrary, for example, in a case where there is a functional block which is intended to perform a high-speed operation, the power supply voltage supplied to the functional block may be temporarily increased.

In the case where the DC power supply circuit 20 is provided at the position where the DC power supply circuit 20 overlaps the semiconductor IC chip 30 in a plan view, it is possible to reduce the area of the multilayer wiring board 10 as compared with a case where the DC power supply circuit 20 is not provided at such a position.

In this embodiment, the DC power supply circuit 20 is provided on the multilayer wiring board 10. As a result, it is possible to obtain a higher degree of freedom of layout of the DC power supply circuit 20 and reduce manufacturing costs of the semiconductor device 1.

Further, in this embodiment, the circuit surface 30a of the semiconductor IC chip 30 faces the lower surface S2 side on which the external connection terminals 50 are provided. As a result, the length of the electrical path between the semiconductor IC chip 30 and the mounting board 60 can be reduced, thereby making it possible to minimize the effect of the wiring resistance on a signal voltage of the semiconductor IC chip 30.

Incidentally, Japanese Laid-Open Patent Publication No. 2004-288793 discloses the multilayer wiring board in which the DC power supply circuit is embedded. However, the semiconductor IC chip to which a power supply voltage is supplied from the DC power supply circuit is not embedded in the multilayer wiring board.

In this embodiment, illustrated is the example where the DC power supply circuit 20 includes the control circuit 25. However, it is not essential that the DC power supply circuit 20 includes the control circuit 25.

It should be noted that in this embodiment, it is not essential to provide the mounting board 60. In other words, FIG. 1 shows the semiconductor device 1 which is in a state of having been mounted on the mounting board. Alternatively, the semiconductor device 1 may be in a state before being mounted on the mounting board. In the following embodiment, an example of the semiconductor device in the latter state (that is, in the state before being mounted on the mounting board) is illustrated.

### Second Embodiment

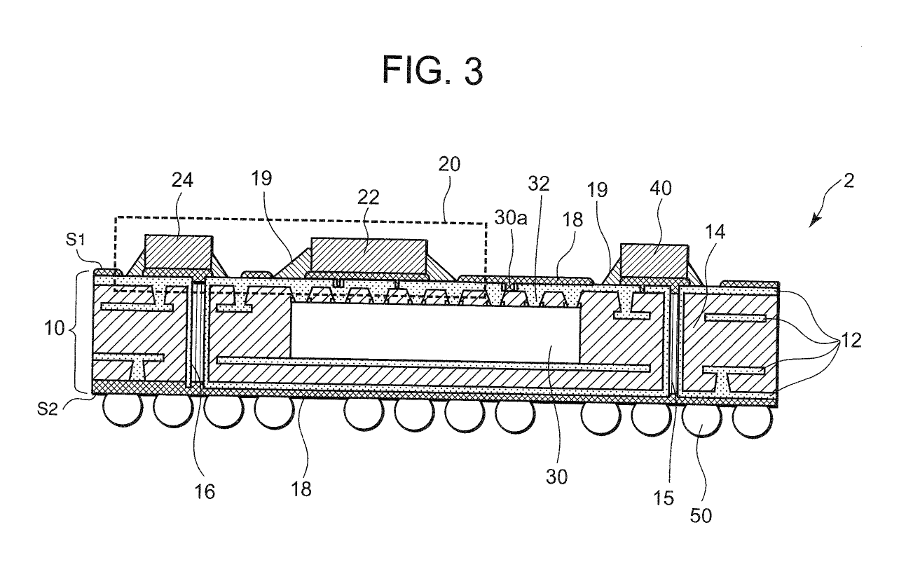

FIG. 3 is a cross-sectional diagram showing a semiconductor device according to a second embodiment of the present invention. In a semiconductor device 2 of this embodiment, the circuit surface 30a of the semiconductor IC chip 30 embedded in the multilayer wiring board 10 faces the upper surface S1 side. As a result, the length of the electrical path between the DC power supply circuit 20 and the semiconductor IC chip 30 can be reduced, thereby making it possible to minimize the effect of the wiring resistance on the power supply voltage of the semiconductor IC chip 30. Other configurations and effects of the semiconductor device 2 are the same as those of the semiconductor device 1 shown in FIG. 1.

### Third Embodiment

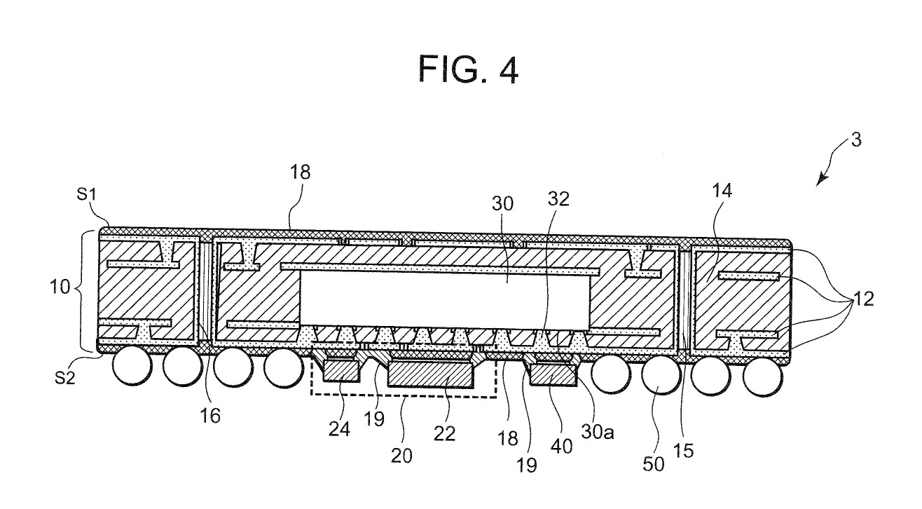

FIG. 4 is a cross-sectional diagram showing a semiconductor device according to a third embodiment of the present invention. In a semiconductor device 3 of this embodiment, the DC power supply circuit 20 and the capacitor 40 are provided on the lower surface S2 of the multilayer wiring board 10. In other words, the DC power supply circuit 20 and the capacitor 40 are provided on the same side on which the external connection terminals 50 are provided. As a result, it is possible to secure a wide space on the upper surface S1 of the multilayer wiring board 10. Further, the circuit surface 30a of the semiconductor IC chip 30 faces the lower surface S2 side on which the DC power supply circuit 20 and the external connection terminals 50 are provided. Accordingly, it is possible to reduce the length of the electrical path between the DC power supply circuit 20 and the semiconductor IC chip 30, and it is possible to reduce the length of the electrical path between the semiconductor chip 30 and the mounting board. In addition, the entirety of the DC power supply circuit 20 overlaps the semiconductor IC chip 30 in a plan view. As a result, it is possible to further reduce the area of the multilayer wiring board 10 as compared with the case where a part of the DC power supply circuit 20 overlaps the semiconductor IC chip 30. Other configurations and effects of the semiconductor device 3 are the same as those of the semiconductor device 1 shown in FIG. 1.

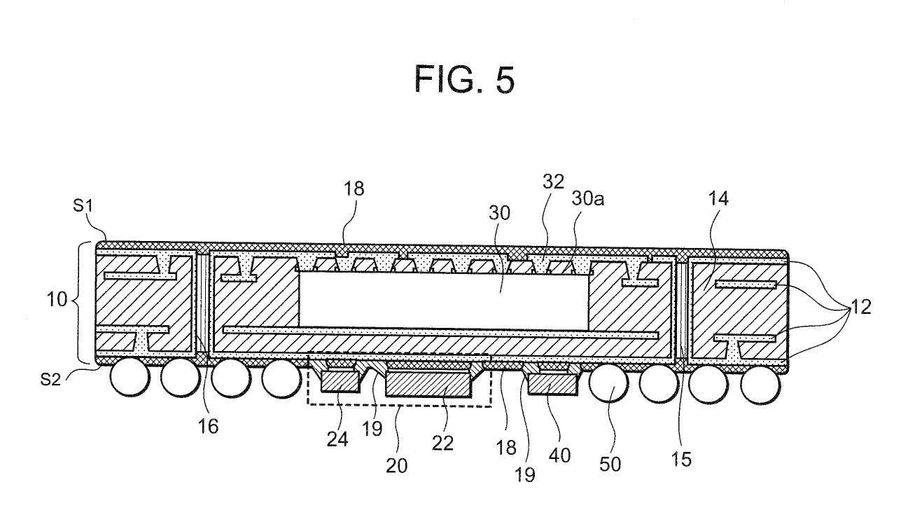

It should be noted that in this embodiment, illustrated is the example where the circuit surface 30a of the semiconductor IC chip 30 faces the lower surface S2 side. Alternatively, as shown in FIG. 5, the circuit surface 30a of the semiconductor IC chip 30 may face the upper surface S1 side.

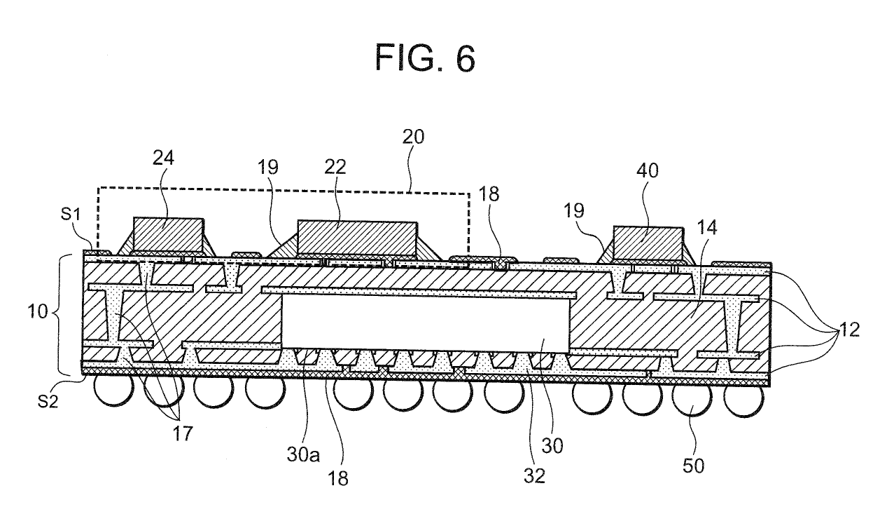

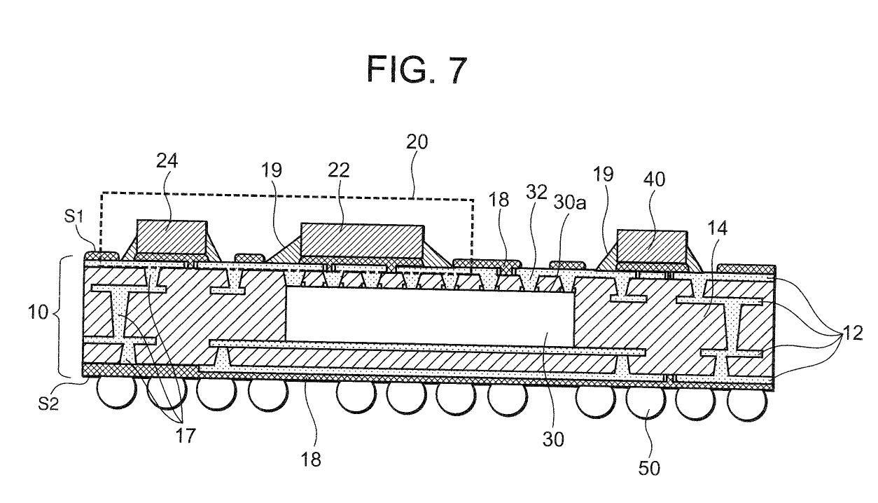

The semiconductor device according to the present invention is not limited to the above embodiments, and various modifications can be adopted. In the above embodiments, illustrated is the example where the electric connection between both the surfaces S1 and S2 of the multilayer wiring board 10 is established by the wirings 12 provided within the penetrating through-holes 16. Alternatively, for example, as shown in FIGS. 6 and 7, the electric connection between both the surfaces S1 and S2 may be established by via plugs 17. The circuit surface 30a of the semiconductor IC chip 30 faces the lower surface S2 side and the upper surface S1 side in FIGS. 6 and 7, respectively. In FIGS. 6 and 7, in the same manner as in FIGS. 4 and 5, the DC power supply circuit 20 and the capacitor 40 may also be disposed on the lower surface S2 of the multilayer wiring board 10.

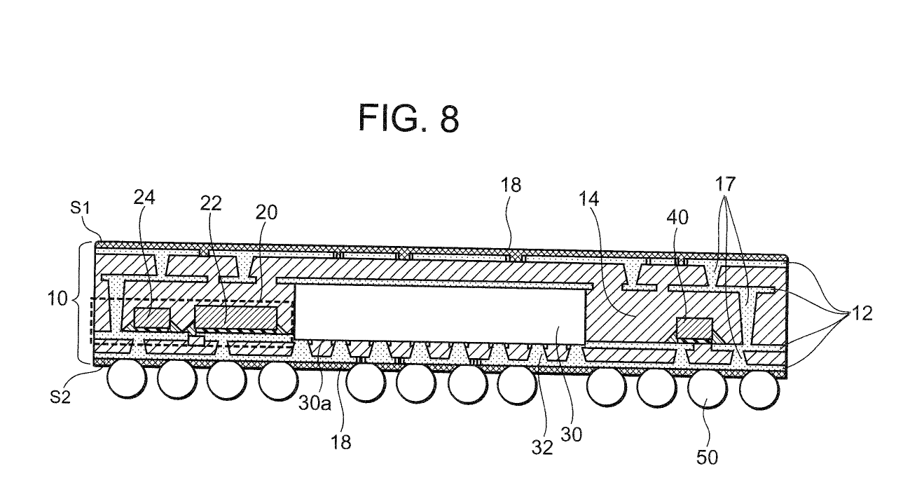

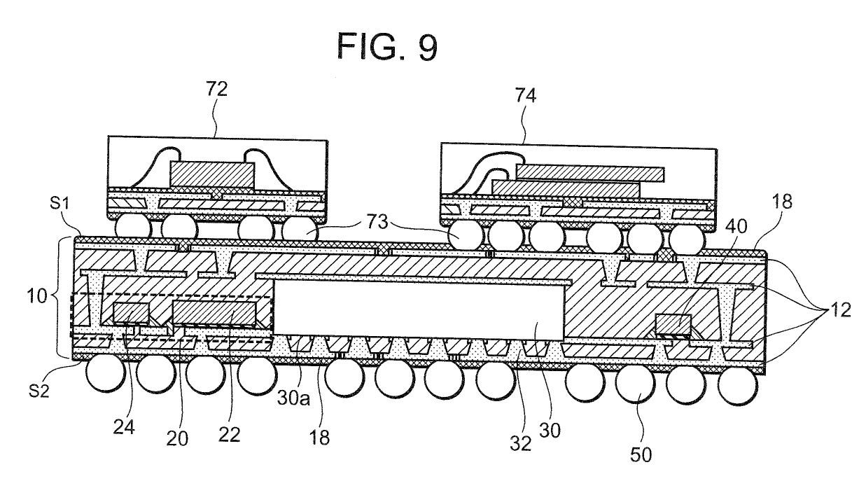

Further, in the above embodiments, illustrated is the example where the DC power supply current 20 is provided on the multilayer wiring board 10 (i.e., on the upper surface S1 or on the lower surface S2). Alternatively, as shown in FIGS. 8 and 9, the DC power supply circuit 20 may be provided in the multilayer wiring board 10. In other words, the DC power supply circuit 20 as well as the semiconductor IC chip 30 may be embedded in the multilayer wiring board 10. In FIGS. 8 and 9, the capacitor 40 is also embedded in the multilayer wiring board 10. Further, in FIG. 9, on the upper surface S1 of the multilayer wiring board 10, electric components 72 and 74 which are provided separately from the DC power supply circuit 20 and the capacitor 40 are mounted through solder balls 73. The electric components 72 and 74 are, for example, package components including a semiconductor memory.

It should be noted that in FIGS. 8 and 9, illustrated is the example where both the surfaces S1 and S2 of the multilayer wiring board 10 are connected to each other through the via plugs 17. Alternatively, similarly to FIG. 1 or the like, both the surfaces S1 and S2 may be connected to each other through the wirings 12 within the penetrating through-hole 16. In addition, in FIGS. 8 and 9, illustrated is the example where the circuit surface 30a of the semiconductor IC chip 30 faces the lower surface S2 side. Alternatively, the circuit surface 30a may face the upper surface S1 side.

Further, in the above embodiments, the four-layer wiring board is illustrated as the multilayer wiring board 10. Alternatively, the number of layers of the multilayer wiring board 10 is not limited thereto as long as the number is equal to or larger than 2.

Further, in the above embodiments, illustrated is the example where the DC power supply circuit 20 is composed of a plurality of electric components. Alternatively, the DC power supply circuit 20 may be composed of an integrated electric component.

What is claimed is:

1. A semiconductor device comprising:
a multilayer wiring board having a semiconductor integrated circuit chip embedded therein; and
a DC power supply circuit provided on said multilayer wiring board to receive a power supply, said DC power supply circuit supplying a power supply voltage to said semiconductor integrated circuit chip.

2. The semiconductor device according to claim 1, wherein said DC power supply circuit is configured to convert a voltage of said power supply into a plurality of voltages having different levels from one another and output said plurality of voltages.

3. The semiconductor device according to claim 2, wherein said DC power supply circuit includes a DC-DC converter circuit.

4. The semiconductor device according to claim 1, wherein said semiconductor integrated circuit chip uses a plurality of voltages having different levels from one another.

5. The semiconductor device according to claim 1, wherein said semiconductor integrated circuit chip includes a plurality of functional blocks.

6. The semiconductor device according to claim 1, wherein said DC power supply circuit has an output voltage which can be controlled by said semiconductor integrated circuit chip.

7. The semiconductor device according to claim 6, wherein said DC power supply circuit has a plurality of output terminals to output said plurality of voltages, and each of said plurality of voltages which are output from each of said plurality of output terminals is variable.

8. The semiconductor device according to claim 1, wherein said DC power supply circuit is provided at a position where said DC power supply circuit overlaps said semiconductor integrated circuit chip in a plan view.

9. The semiconductor device according to claim 1, further comprising a decoupling capacitor provided on said multilayer wiring board.

10. The semiconductor device according to claim 1, further comprising a mounting board having said multilayer wiring board mounted thereon.
